(19) United States
(12) Patent Application Publication
(10) Pub. No.: US 2012/0099753 A1
(43) Pub. Date: Apr. 26, 2012

(54) Backplate for Microphone

(75) Inventors: Casper van der Avoort, Waalre (NL); Andreas Bernardus Maria Jansman, Nuenen (NL); Geert Langereis, Eindhoven (NL); Twan van Lippen, Bladel (NL); Hilco Suy, Eindhoven (NL)

(73) Assignee: KNOWLES ELECTRONICS ASIA PTE. LTD., Itasca, IL (US)

(21) Appl. No.: 13/263,325

(22) PCT Filed: Apr. 6, 2010
(86) PCT No.: PCT/IB2010/051484

§ 371 Date: Jan. 3, 2012

(30) Foreign Application Priority Data
Apr. 6, 2009 (EP) 09157442.6

(51) Int. Cl. H04R 9/08; H04R 31/00; B81C 1/00

(52) U.S. Cl. 381/361; 29/896.23; 29/594

(57) ABSTRACT

A microphone has a membrane (20) mounted to vibrate in response to pressure fluctuations, a backplate (30) facing the membrane and being more rigid than the membrane, and circuitry (95) for sensing the vibrations relative to the backplate, the backplate being prestressed and having a geometry such that a response of the backplate to structure borne vibration matches a corresponding response of the membrane. This can help reduce or minimize relative movement between these surfaces caused by structure borne vibration and hence improve the signal-to-noise ratio of the microphone. The geometry can be a hub and spoke arrangement.

### FIELD OF THE INVENTION

This invention relates to microphones, to packages or devices having such microphones and to corresponding methods of designing or manufacturing the same.

### BACKGROUND OF THE INVENTION

In many systems having microphones, such as mobile phones, there is demand to reduce size and manufacturing costs. Electronics associated with the microphone may comprise pre-amplifiers (for the high-impedance capacitive transducer), biasing circuit (for electret type microphones at least), A/D converters and signal processing. PCB mounting is often preferred by mobile phone manufacturers; to conform with existing high speed assembly lines. The commonly used electret microphones do not have the desired form factor for integration with their associated electronics. It is known to use MEMS type microphones, as discussed in “the top ten reason for using MEMS in cell phones” In-Stat MDR, September 2003. One advantage is that such MEMS type microphones can be less sensitive to damage by heating during soldering operations.

Typically a condenser microphone consists of four elements; a fixed, perforated backplate, a highly compliant, moveable diaphragm (which together form the two plates of a variable air-gap capacitor), and circuitry such as a voltage bias source, and a buffer amplifier. The diaphragm must be highly compliant and precisely positioned relative to the backplate, while the backplate must be more rigid so as to remain stationary and present a minimum of resistance to the flow of air through it. Achieving all of these characteristics in microphones below 1 mm in size using integrated circuit materials has been challenging. Typical stress levels in integrated circuit thin films, if not relieved in the finished diaphragm, are many times greater than the levels at which the diaphragm becomes unusable due to over-stiffening or buckling. Compliance tends to decrease very rapidly with decreasing size for a given diaphragm material and thickness. This patent proposes providing an alternative diaphragm and backplate construction in which the form of the diaphragm is based on a cantilever and in which alternate configurations for venting the backplate, appropriate for sub-mm-size microphones are used.

It is known to provide prestressing to the backplate to increase rigidity. It is also known to provide perforations to reduce air damping effects.

WO 84/03410 shows providing a silicon backplate and insulating layer to increase the rigidity of the backplate. The backplate can be formed by patterning a layer and can have spokes to provide additional rigidity. Holes may be formed between each of the spokes.

US 2007261910 shows forming a backplate in the form of an opposing electrode plate which is laminated on the vibration electrode plate with a sacrificial layer (silicon oxide film) interposed in between. It is separated from the vibration electrode plate by removing the sacrifice layer in the last stage of the manufacturing process. This reduces the possibility of the vibration electrode plate sticking to the opposing electrode plate. In order to increase the rigidity of the opposing electrode plate and also to reduce the resistance of a fluid that passes through an etched hole in the opposing electrode plate, the hole of the opposing electrode plate is made smaller than etched holes in the vibration plate.

An article (ISBN: 0-9666135-7-0) “On Design of a Backplate used in a Hearing Aid” by N. L. Pedersen, Technical Proceedings of the 2000 International Conference on Modeling and Simulation of Microsystems, shows optimising a topology of a MEMs formed prestressed backplate for a microphone, and shows maximising the change in capacitance by maximising stiffness. This involves finding topologies of connections between a central perforated part and an outer frame in order to maximise a first eigenfrequency.

### SUMMARY OF THE INVENTION

An object of the invention is to provide microphones, packages or devices having such microphones and corresponding methods of designing or manufacturing the same.

According to a first aspect, the invention provides:

A microphone having a membrane mounted to vibrate in response to pressure fluctuations, a backplate facing the membrane, and circuitry for sensing the vibrations relative to the backplate, the backplate having a geometry such that a response of the backplate to structure borne vibration matches a corresponding response of the membrane.

With respect to the terms “spokes” and “strings” these are used throughout this document. Applicants do not intend any difference.

The present invention can help reduce or minimize relative movement between these surfaces caused by structure borne vibration and hence improve the signal-noise ratio of the microphone without consuming additional power. It represents a different approach from the conventional aim of making the backplate as rigid as possible. Frequency matching of membrane and backplate, which is provided to cancel structure-borne sound, might also be achieved by matching stresses in the layers of membrane and backplate, and/or having different diameters for both. The present solution gives both the same outer diameter and can deal with large differences of stress in the two layers. The present solution is purely geometrical.

Embodiments of the invention can have any other features added, some such additional features are set out in dependent claims and described in more detail below.

Other aspects provide corresponding packages or devices having such microphones, or corresponding methods of designing or methods of manufacturing such microphones, packages or devices.

Any of the additional features can be combined together and combined with any of the aspects. Other advantages will be apparent to those skilled in the art, especially over other prior art. Numerous variations and modifications can be made without departing from the claims of the present invention. Therefore, it should be clearly understood that the form of the present invention is illustrative only and is not intended to limit the scope of the present invention.

### BRIEF DESCRIPTION OF THE DRAWINGS

How the present invention may be put into effect will now be described by way of example with reference to the appended drawings, in which:

FIG. 1 shows a schematic cross section view of a microphone,

FIG. 2 shows a schematic plan view of a backplate according to an embodiment,

FIG. 3 shows an example of a method having design steps for the backplate pattern to enable it to have a matched resonance frequency

FIG. 4 shows a plan view of part of another embodiment of the backplate,

FIG. 5 shows a graph of electrical characteristics according to an embodiment, and

FIG. 6 shows an example incorporated in a package in a device.

### DETAILED DESCRIPTION OF THE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

The term “comprising”, used in the claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, Figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

How to put the invention into practice will now be described by a detailed description of several embodiments of the invention. It is clear that other embodiments of the invention can be configured according to the knowledge of persons skilled in the art without departing from the technical teaching of the invention, the invention being limited only by the terms of the appended claims.

### Capacitive Microphones

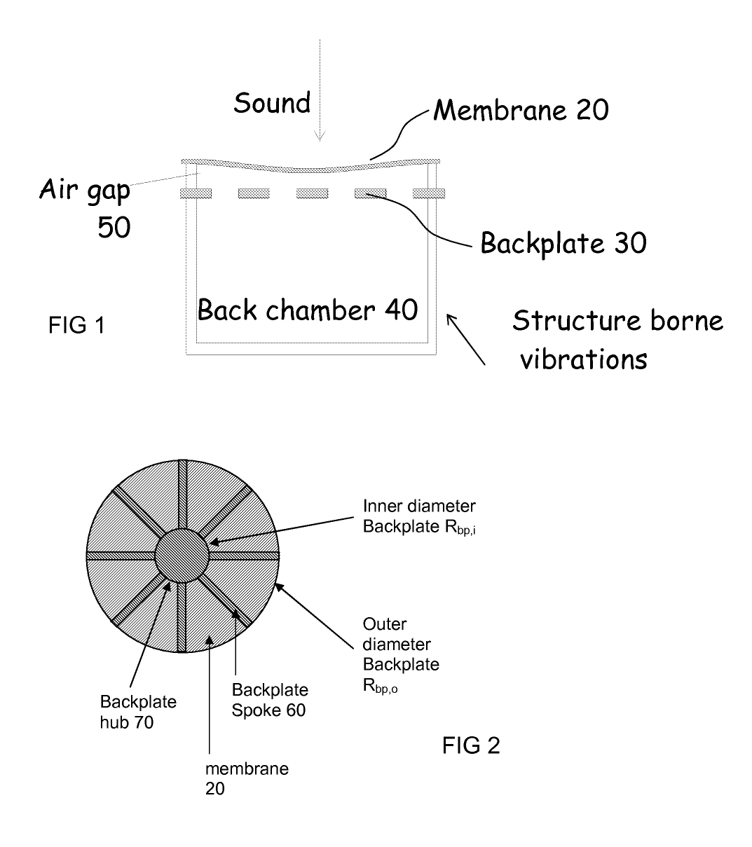

By way of introduction, a capacitive microphone having the structure as schematically drawn in FIG. 1 will be discussed. It shows a membrane 20, a backplate 30 facing the membrane, and a back chamber 40. An air gap 50 is provided between the membrane and the backplate. Sound pressure waves forces the membrane to vibrate due to a pressure difference over the membrane. For a good omni-directional performance, the back side of the membrane should be acoustically isolated. The membrane is connected to an acoustically closed back chamber 40 in this case. This influences the membrane compliance and the lower cut-off frequency. A tiny hole in the back chamber is typically provided to compensate for slow changes in atmospheric pressure.

In order to sense sound, an electrically detectable signal, proportional to the sound pressure should be detectable. Using a conductor, changes in relative distance between the two parallel plates caused by an acoustical signal will results in changes in capacity. Consequently, an electrically detectable signal is available due to modulation of the air gap. In order to operate as a capacitor, both the membrane as well as the backplate should contain conducting surfaces or be formed of conducting materials. For ideal acoustical transduction, the backplate is a stiff plate and only the membrane is displaced by the acoustic pressure. Note that the membrane and backplate are typically made in a silicon MEMS process while the back-chamber can be defined by the package or by the product itself. MEMS microphone principles are explained further in:

P. R. Scheeper, A. G. H. van deer Donk, W. Olthuis and P. Bergveld, Fabrication of silicon condenser microphones using single wafer technology, Journal of Microelectromechanical Systems, Vol. I, No. 3, September 1992 M. Pedersen, W. Olthuis and P. Bergveld, An Integrated silicon capacitive microphone with frequency-modulated digital output, Sensors and Actuators A69 (1998), pp. 267-275 and J. J. Neumann Jr. and K. J. Gabriel, CMOS MEMS membrane for audio-frequency acoustic actuation, Sensors and Actuators A95 (2002), pp. 175-182. MEMS microphones for mobile phones have become of interest for a number of reasons. Firstly, in order to integrate electronics with microphones into System in Package (SiP) solutions, the conventional electret microphones do not have the desired form factor. Electronics in the microphone may comprise pre-amplifiers, biasing circuits, A/D converters, signal processing and bus drivers for example. Secondly PCB mounting is preferred by mobile phone and other device manufacturers. Other factors are set out in the publications referred to above.

### Body Noise Cancellation

Due to the mechanical vibrations the two parallel plates of the capacitor will undergo a relative movement and an unwanted electrical signal is detected. Body noise, or structure borne sound, is the disturbing effect of mechanical vibrations resulting into an electrical output on the microphone.

One example is crosstalk of a mobile phone's own speaker into the microphone which has a nonlinear transfer function. Such effects cannot be compensated for by signal processing, therefore they have to be minimized by a microphone design, having less sensitivity to mechanical vibrations.

To avoid effect of mechanical vibrations (at audible frequencies, i.e. far below the fundamental resonance of either membrane or backplate), the membrane and backplate should be designed in such a way that they show a co-phased response of equal amplitude for mechanical vibrations. Only in that case, there is no electrical output due to mechanical vibrations.

### Implementing Body Cancellation

To implement Body Noise Cancellation (BNC) the resonance frequency of the backplate should be matched to that of the membrane. In addition to the resonance frequency matching, which is the most important parameter for BNC, the deflection profile is an additional factor. After mechanical excitation, it is the output signal or change in capacitance that should be reduced or annihilated. Equal vibration amplitudes of two distinct vibration profiles however, will still cause a modulated output signal. Ideally, one would like to have both the membrane and backplate having the same resonance frequency and deflection profile. For a practical implementation of BNC into current designs and for compatibility with the current process technology, it is desirable to look at a solution which affects only the backplate. Moreover, if possible, for simplicity and minimising of changes to existing manufacturing lines, it should only act on the layout of the backplate, rather than other factors such as three dimensional shape, materials and so on. Other options can be conceived.

Therefore the embodiments described involve implementing BNC by having a backplate prestressed and having a geometry such that a response of the backplate to structure borne vibration matches a corresponding response of the membrane by redesigning the footprint of the backplate. This can be implemented by matching the resonance frequency of the highly stressed backplate to the membrane, so as to reduce or minimize body noise.

### Additional Features

Some additional features are as follows: the geometry can comprise a central hub and spokes between the hub and a surrounding frame. Other configurations are conceivable, though are likely to be more complex to analyse. The backplate can comprise a patterned layer formed by a MEMS process resulting in the prestressing. The match can comprise a match of frequency of fundamental resonance of the parts to within 20% .

The membrane can have a thickness of 0.1 to 0.5 microns, and a diameter between mountings of 0.5 to 2.5 mm. The backplate can have a diameter between mountings of 0.5 to 2.5 mm, and a thickness of 2 to 4 microns. The backplate can have spokes of cross section area less than 25 square microns.

The hub can have a diameter of less than half a diameter of the backplate. The spokes can have a width of less than 2% of the diameter of the backplate. The microphone can have two or more of the membranes and the backplates, and the circuitry be arranged to sense a capacitance of the membranes coupled in parallel. This can increase the total capacitance value being sensed. The backplate can be substantially planar and have a thickness at least five times greater than a thickness of the membrane.

The microphone can be incorporated in a package and the package be incorporated in a device.

Another aspect provides a method of manufacturing a microphone by forming the membrane so as to be mounted to vibrate in response to pressure fluctuations, forming the backplate facing the membrane and so as to be more rigid than the membrane, and forming the circuitry for sensing the membrane vibrations relative to the backplate, the backplate being formed to be prestressed and to have a geometry such that a response of the backplate to structure borne vibration matches a corresponding response of the membrane.

The method can have the step of forming the backplate by patterning a layer formed by a MEMs process to create the geometry.

Another aspect provides a method of creating a pattern for a backplate of a microphone, the microphone having a membrane mounted to vibrate in response to pressure fluctuations, the backplate being arranged to face the membrane and be more rigid than the membrane, and the microphone having circuitry for sensing the membrane vibrations relative to the backplate, the backplate being prestressed and having a geometry having a hub and spokes such that a response of the backplate to structure borne vibration matches a corresponding response of the membrane, the method having the steps of: determining the response of the membrane, selecting a cross section for the spokes, determining a mass for the hub in terms of the response of the membrane, an amount of the prestressing, a diameter of the backplate, material density and the spoke cross sections, and determining a number of spokes and a diameter of the hub from the mass, to create the pattern.

FIG. 2 shows a cobweb design with matched resonance frequency.

A construction proposed for a MEMS microphone, in particular for the backplate, is matched to the membrane so as to reduce the noise due to mechanical vibrations. An important performance parameter is the sensitivity to structure borne sound, which is governed by the undesired relative movement between the backplate and membrane due to mechanical vibrations on the suspension of the microphone. When the two-dimensional layout of the backplate is such that its fundamental resonance frequency is identical to the membrane resonance frequency, no relative movement between the backplate and membrane will occur for mechanical vibrations acting on the body containing both the membrane and the backplate. In regular microphone operation, sound pressure will cause a significant movement of the membrane, leaving the backplate unaffected because of its acoustic transparency. This backplate geometry can result in a higher electrical signal output from the microphone in some cases, and can result in higher electrical signal, relative to the background electrical signal. When the present invention is not applied, the electrical signal will be degraded, as the membrane and microphone show different mechanical responses when the membrane is excited by airpressure fluctuations and the backplate is excited by these airpressure fluctuations through structure coupling.

Tailoring the backplate geometry such that the frequency responses of membrane and backplate match each other gives a good approximation even if the deflection profiles are not ideally matched.

The fundamental resonances of both the membrane and the backplate are typically well above audible frequencies. In a one-dimensional approximation however, the amplitudes of their responses to excitation at audible frequencies will be a function of the value of the fundamental resonance frequency. Hence, frequency matching leads to response amplitude matching to a sufficiently good approximation. When the resonance frequency of the backplate and membrane are within 20%, an estimated 10 dB improvement in noise suppression is expected with respect to mechanical vibrations. For an improvement of 20 dB, the resonance frequencies need to match to within approximately 5%. In current designs for stress controlled backplates, this could be realized by optimizing material parameters (such as stress) which is difficult to control in mass production.

Both the membrane as well as the backplate are typically produced in Silicon, but experience different residual stresses after fabrication. The membrane (in a currently manufactured form typically a disk of 920 micron diameter with 0.3 micron thickness) and the backplate (currently a disk of equal diameter with 3 micron thickness) are under tensile stress of 30 MPa and 180 MPa, respectively. For a solution that does not require a different process flow, only the geometry or footprint of the backplate is allowed to change. Hence, using the mentioned thicknesses and pre-stresses, a design of footprint of the backplate should result in a membrane and backplate having nearly equal resonance frequencies.

FIG. 2 shows a plan view of an example designed with a hub 70 and spokes 60, rather than a solid disk, the resonance frequency can be predicted by analyzing pre-stressed strings. The outline need not be circular, though other shapes are harder to analyse accurately. The center of the cobweb is a massive disk, acting by centrally massloading the strings. The sparsity of the design ensures the required acoustical transparency of the backplate. Moreover, the sparsity allows the frequency of the thick, highly stressed backplate to be matched to the thin, less stressed membrane.

### Some Design Principles

As stated, the prestressed solid backplate will be re-designed to have a footprint like a cobweb of prestressed strings with a solid central disk. Without being limited by theory, prediction of an eigenfrequency of such a backplate is proposed based on a model for the fundamental frequency is derived based on energy. Using a piecewise linear shape function (string-disk-string as ramp-flat-ramp), the eigenfrequency versus prestress or tension T can be expressed as

Ω₀=\sqrt{bT},

where the constant b is depending on the assumed modeshape and reads

$$b = \frac{24 A}{6 LM + 2 {AL}^{2} ρ}$$

The material's Young's modulus E only appears in term a. This means that for higher tension T, the frequency is controlled by tension and mass M. The addition of mass results in a flatter frequency versus tension curve, rendering the frequency of the design less sensitive to pre-stress.

| symbol | units | Remarks |
|---|---|---|
| T, E | N m⁻² | Tension, Young's modulus |
| M | kg | Mass for massloading |
| L | m | Length of string, excluding mass |
| I | m⁴ | Moment of inertia |
| A | m² | Cross-sectional area of string |
| ρ | kg m⁻³ | Mass density |

Length L is the length of the full string; the integrals were taken up to L/2. Moreover, the full mass M has to be entered, not the mass per string.

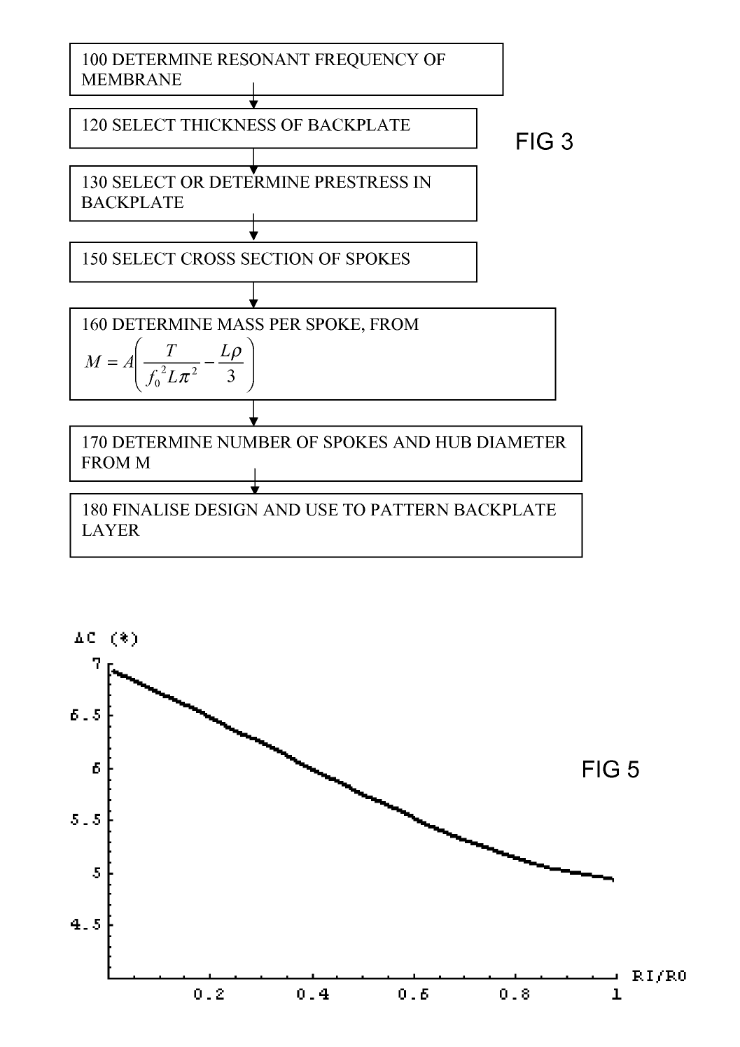

FIG. 3 shows an example of design steps

The expressions for the fundamental resonance of a massloaded string and hence of the proposed cobweb are found to be in accordance with the results found in finite element simulations. Therefore, a backplate can be designed, that allows frequency matching of membrane and backplate.

As an example, the required geometry for the backplate to match the 90 kHz resonance of the 0.3 micron thick membrane under 30 MPa prestress will be derived as follows. In accordance with the process flow as it is for the current backplate, the design is for a backplate layer having an overall thickness of 3 microns and an expected prestress of 180 MPa, when a solid disk would be designed as backplate. In the CobWeb structure, the stress is partially released: the hub contracts to a stress-free state, while the strings are stretched further. For such a high tension, the linear mode-shape assumption can be used. Using the derived expression for frequency, one can rewrite the necessary mass M at the center to be

$$M = A ( \frac{T}{{f}_{0}^{2} L {π}^{2}} - \frac{L ρ}{3} ) .$$

The following values are used:

| | | | | Cross- |
|---|---|---|---|---|
| Desired | | Length excluding | | section |
| frequency | Pre-stress | central disk | Mass density | string |
| f₀ | T | L | ρ | A |
| 90 kHz | 180 10⁶ Pa | 920 mu * 0.8 | 2300 kg m⁻³ | 3 mu * 6 mu |

Using these values, the central and rigid mass should be M=4.49 10⁻¹¹ kg. This is the mass per string. The number of strings in this case follows from the true mass of the central disk. Assuming a circular central disk of diameter 920 mu*0.2, the number of strings in the cobweb should be N=Mₜₒₜ/M=4.09.

Should the number of strings be desired to be higher, for the same diameter of the central disk, one can diminish the cross-sectional area A of the strings.

The process is set out in FIG. 3. At step 100, the resonant frequency of the membrane is determined, by measurement or analysis. At step 120 a thickness of backplate layer is selected or determined. At step 130 the amount of prestress in the backplate is selected or determined. Then a cross section of the spokes is determined at step 150, and the mass per spoke can then be determined at step 160 according to the equation for M set out above. At step 170 the number of spokes and the hub diameter can be determined from M. At step 180 the design can be finalised and used to pattern the backplate layer.

### Release Under Tension

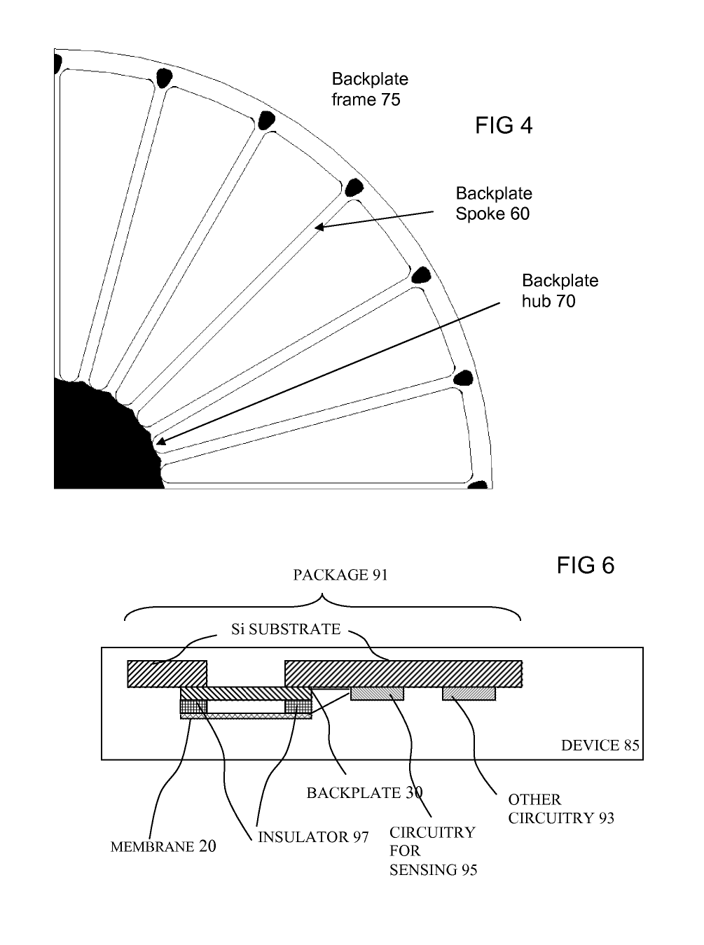

The process flow for the production of MEMS microphones has demonstrated to result in prestressed backplates. Step-wise thickness variations or sharp angles in planar geometry will cause additional stress localisation after release in production. To avoid failure of the backplate, one should avoid stress accumulation by design. The thickness of the backplate is uniform, but the use of strings will inevitably lead to corners. Static calculations of a cobweb-design with rounded-off corners show that the design can be made such, that stress accumulation after release is negligible. FIG. 4 shows an example of a design showing a quarter of the backplate in plan view in which N=6 and a fillet radius of 10 μm has been used at the corners.

This Figure also shows the backplane has a frame 75 around the perimeter of the backplane, where the spokes end. The frame is assumed to be mounted on a substrate, or form part of the substrate on which the membrane is also mounted. The frame can be larger than that shown, and may extend to form electrical connections to circuitry for sensing for example.

In this Figure darkened areas are those of lower stress.

FIG. 5 shows electrical performance:

Sound waves lead to vibration of the membrane, relative to the silent backplate. This vibration is sensed by measuring the variation in capacitance between membrane and backplate.

For a conventional design (membrane and backplate are (nearly) solid discs. For typical dimensions the capacitance in the rest situation (static capacitance) is 3 pF. For membrane amplitudes equal to one tenth of the gap between membrane and backplate, the change in capacitance is 5% (150 fF).

For the new cobweb design, the capacitance during vibration of the membrane is plotted in FIG. 5 as a function of the radius of the central disc (RI), normalised to the maximum radius (R0). Again this is for membrane amplitudes of one tenth of the gap. For larger amplitudes, severe nonlinearities in the electrical response will show up which is undesirable in any microphone. For RI=R0, the conventional situation of a solid full-size backplate is reached. The Figure shows the change in capacitance with respect to the static capacitance at a rest situation. Clearly, when RI becomes small the absolute change in capacitance is smaller than for the conventional case. However, the change, normalised to the static capacitance is larger (up to 7% or 8% for realistic cases) than the 5% Figure for the conventional backplate.

If it is desired to keep the absolute change in capacitance as high as in the conventional case (150 fF), one can

Bring the mass from the center outwards along the strings. More mass (i.e. more occupied area) is then needed in order to obtain the proper eigenfrequency.

Fill the empty space between the spokes with mass.

Both variations tend to reduce the improvement seen in the values normalised to the static capacitance. As another alternative, one can have several of these microphones coupled in parallel (at the cost of space and costs).

### Structure Borne Sound Response

The microphone incorporating our solution will be insensitive to structure borne sound or mechanical vibrations transmitted to the microphone. At the very heart of electrical signal generation, the present microphone cancels out the electrical effect of such vibrations.

FIG. 6 shows a package and device

FIG. 6 shows a schematic cross section view of an example of the backplate incorporated into a package in a device. The package 91 has a Si substrate 90, which has an aperture over which the backplate 30 extends. This forms part of the back chamber for the microphone. The package is inside a device 85, a body of which closes off the aperture to form an end of the back chamber. An insulator 97 separates the backplate and membrane 20 at the periphery of the backplate. The backplate may have the design shown in FIG. 2 or 4 or other design with matched resonance frequency. The membrane and backplate form capacitor plates and are connected by leads to circuitry 95 for sensing the changes in capacitance caused by audio pressure waves. Such circuitry can be conventional circuitry for outputting a digital or analog signal representing the capacitance or any characteristic of the sound. This can follow established practice which need not be described in detail here. Some of the circuitry can be located elsewhere, and at minimum, the circuitry on the substrate can be simply electrical contacts to enable external circuitry to be coupled electrically to the membrane and the backplate. Other circuitry 93 for other functions may be incorporated on the same substrate, or on other PCBs in the same package 91.

The package can be an integrated microphone with associated electronics, and typically has a MEMS microphone chip, a CMOS chip and some external passive components in a single package. The electronics may comprise a selection from for example: a pre-amplifier; a voltage multiplier; an A/D converter and digital signal processing circuitry, depending on the application. The external passive components can be used for the voltage multiplier or for decoupling purposes for example. The device can be a mobile phone, a mobile computing device, a headset, or other computing device for any application for example.

Other variations can be envisaged within the scope of the claims.

1. A microphone comprising a membrane mounted to vibrate in response to pressure fluctuations, a backplate facing the membrane and being more rigid than the membrane, and circuitry for deriving a signal according to the membrane vibrations relative to the backplate, the backplate being prestressed and having a geometry such that a response of the backplate to structure borne vibration matches a corresponding response of the membrane.

2. The microphone of claim 1, wherein the backplate geometry comprises a central hub and spokes between the hub and a surrounding frame.

3. The microphone of claim 1, wherein the backplate comprises a patterned layer formed by a MEMS process resulting in the pre-stressing.

4. The microphone of claim 1, wherein the match between the response of the backplate and the response of the membrane comprises a match of frequency of fundamental resonance of the parts to within 20%.

5. The microphone of claim 1, wherein the membrane has a thickness of 0.1 to 0.5 microns, and a diameter between mountings of 0.5 to 2.5 mm.

6. The microphone of claim 1, wherein the backplate has a diameter between mountings of 0.5 to 2.5 mm, and a thickness of 2 to 4 microns.

7. The microphone of claim 2, wherein the backplate has spokes of cross section area less than 25 square microns.

8. The microphone of claim 2, wherein the hub has a diameter of less than half a diameter of the backplate.

9. The microphone of claim 2, wherein the spokes have a width of less than 2% of the diameter of the backplate.

10. The microphone of claim 1, further comprising one or more additional membranes, and wherein the circuitry is arranged to sense a capacitance of the membranes coupled in parallel.

11. The microphone of claim 1, wherein the backplate is substantially planar and has a thickness at least five times greater than a thickness of the membrane.

12. A package for an electrical device, the package comprising a substrate and a microphone on the substrate, wherein the microphone comprises a membrane mounted to vibrate in response to pressure fluctuations, a backplate facing the membrane and being more rigid than the membrane, and circuitry for deriving a signal according to the membrane vibrations relative to the backplate, the backplate being prestressed and having a geometry such that a response of the backplate to structure borne vibration matches a corresponding response of the membrane.

13. A method of manufacturing a microphone, the method comprising the steps of: forming the membrane so as to be mounted to vibrate in response to pressure fluctuations, forming a backplate facing the membrane and so as to be more rigid than the membrane, and forming circuitry for sensing the membrane vibrations relative to the backplate, the backplate being formed to be prestressed and to have a geometry such that a response of the backplate to structure borne vibration matches a corresponding response of the membrane.

14. The method of claim 13 further comprising the step of forming the backplate by patterning a layer formed by a MEMs process to create the geometry.

15. A method of creating a pattern for a backplate of a microphone, the microphone having a membrane mounted to vibrate in response to pressure fluctuations, the backplate being arranged to face the membrane and be more rigid than the membrane, and the microphone having circuitry for sensing the membrane vibrations relative to the backplate, the backplate being prestressed and having a geometry having a hub and spokes such that a response of the backplate to structure borne vibration matches a corresponding response of the membrane, the method having the steps of:
determining the response of the membrane,
selecting a cross section for the spokes,
determining a mass for the hub in terms of the response of the membrane, an amount of the prestressing, a diameter of the backplate, material density and the spoke cross sections, and
determining a number of spokes and a diameter of the hub from the mass, to create the pattern.
